(19) United States
(12) Patent Application Publication
(10) Pub. No.: US 2009/0166882 A1
(43) Pub. Date: Jul. 2, 2009

(54) METHOD FOR FORMING METAL LINE IN SEMICONDUCTOR DEVICE

(76) Inventor: Seong-Hee Jeong, Gangnam-gu (KR)

Correspondence Address: SHERR & VAUGHN, PLLC, 620 HERNDON PARKWAY, SUITE 200, HERNDON, VA, 20170, US

(21) Appl. No.: 12/192,071

(22) Filed: Aug. 14, 2008

(30) Foreign Application Priority Data
Dec. 26, 2007 (KR) 10-2007-0137006

(51) Int. Cl. H01L 23/48; H01L 21/44

(52) U.S. Cl. 257/774; 438/675; 257/E23.01; 257/E21.476

(57) ABSTRACT

A method for forming a metal line in a semiconductor device includes patterning a part of a first interlayer insulating film over a semiconductor substrate to form a contact hole therein, depositing a first metal in the contact hole to form a metal contact plug, forming a second interlayer insulating film over a semiconductor substrate where the metal contact plug is formed, etching the second interlayer insulating film to form a trench, removing residual gases from the formation of the metal contact plug after the formation of the trench, and depositing a second metal in the trench to form a metal film connected to the metal contact plug. Accordingly, it is possible to avoid the etching of the contact plug by removing the residual gases such as carbon and fluorine, after the formation of a trench.

The present application claims priority under 35 U.S.C. 119 to Korean Patent Application No. 10-2007-0137006 (filed on Dec. 26, 2007), which is hereby incorporated by reference in its entirety.

### BACKGROUND

Copper lines used for improving the operation speed of a semiconductor device may be formed using a damascene process, due to difficulties in etching processes. A damascene process may be a dual damascene process and a single damascene process.

In a dual damascene process, a via plug and a copper line are formed at the same time. An etching stopper film and an interlayer insulating film may be laminated in a multilayer form. These films are etched to form a via hole and a trench. A diffusion preventing film and a seed layer are formed over the top of the entire structure including the via hole and the trench. A copper layer is deposited thereon by an electroplating technique, to fill the trench and via hole. The copper line is finished by planarizing the copper layer by a CMP process.

However, when forming a contact hole, the deposition of copper may bring about the concern for contamination of a lower transistor by diffusion of copper atoms. Therefore, the single damascene process has been used recently. In a single damascene process, tungsten is deposited in the contact hole and a copper line is formed only over the top part thereof.

FIG. 1 is a cross-sectional view of a process for forming a copper line in a semiconductor device by a related single damascene process. As shown in FIG. 1, a second interlayer insulating film 103 is deposited over a semiconductor substrate 100 where a first interlayer insulating film 101 and a tungsten contact plug 102 are formed. Then, a trench pattern is formed and a trench is etched. A copper barrier metal film 104 and copper 105 is deposited thereon.

In a process for forming a contact hole for the tungsten contact plug 102, fluorine is extensively used. A large amount of carbon is also used for achieving the proper selection ratio of a photoresist pattern formed to etch the first interlayer insulating film 101. That is, after forming a photoresist pattern over top of the first interlayer insulating film 101, a contact hole is formed using fluorine gas as a main etchant. A large amount of carbon is used for the proper selection ratio of the photoresist pattern to etch the first interlayer insulating film 101.

Next, tungsten, which is a metal, is deposited in the contact hole, to form a tungsten contact plug 102. Since a related method for forming a contact hole uses a large amount of fluorine and carbon, a seam or void may exist where the tungsten contact plug and the copper deposited in the trench meet. If the size of this seam or void is too large, excess fluorine may be introduced to the tungsten and thus the tungsten is etched in a WF₆ form. Due to the etching of the tungsten, the seam in the tungsten contact plug may become much larger, and the copper may also be contaminated by fluorine after the formation of the tungsten contact plug.

### SUMMARY

Embodiments relate to a semiconductor device, and more particularly, to a method for forming a metal line in a single damascene process and a semiconductor device formed using the same. Embodiments relate to preventing a tungsten contact from being etched by fluorine by removing carbon, as well as fluorine remaining after the formation of a tungsten contact plug.

Embodiments relate to method for forming a metal line in a semiconductor device which includes patterning a part of a first interlayer insulating film over a semiconductor substrate to form a contact hole therein, depositing a first metal in the contact hole to form a metal contact plug, forming a second interlayer insulating film over a semiconductor substrate where the metal contact plug is formed, etching the second interlayer insulating film to form a trench, removing residual gases from the formation of the metal contact plug after the formation of the trench, and depositing a second metal in the trench to form a metal film connected to the metal contact plug.

Embodiments relate to a semiconductor device including a first interlayer insulating film formed over a semiconductor substrate and having a patterned contact hole therein. A metal contact plug of a first metal is formed in the contact hole. A second interlayer insulating film has a trench over the semiconductor substrate having the metal contact plug formed thereon. A metal film of a second metal is formed in the etched trench and connects to the metal contact plug.

### DRAWINGS

FIG. 1 is a cross-sectional view illustrating a related process for forming a metal line.

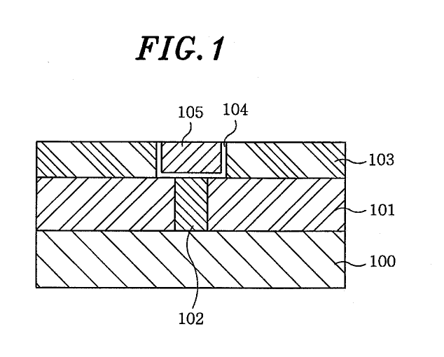

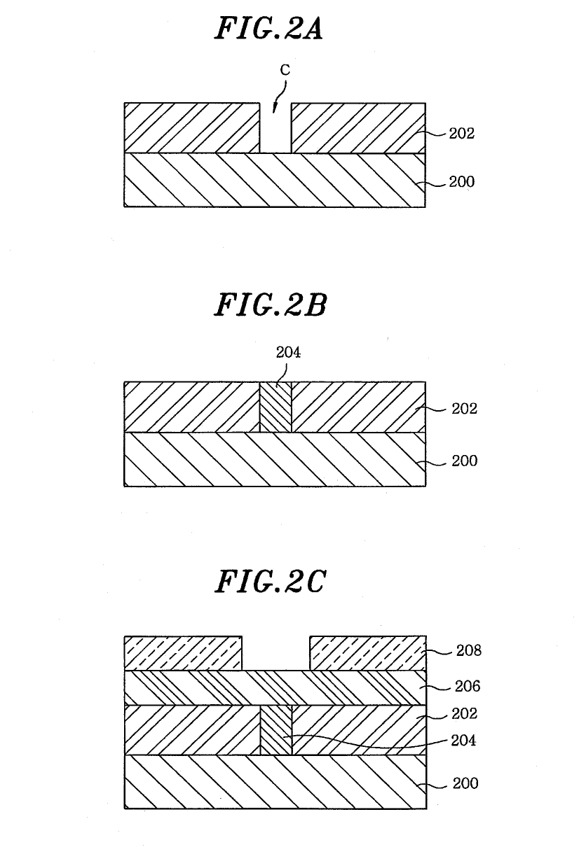

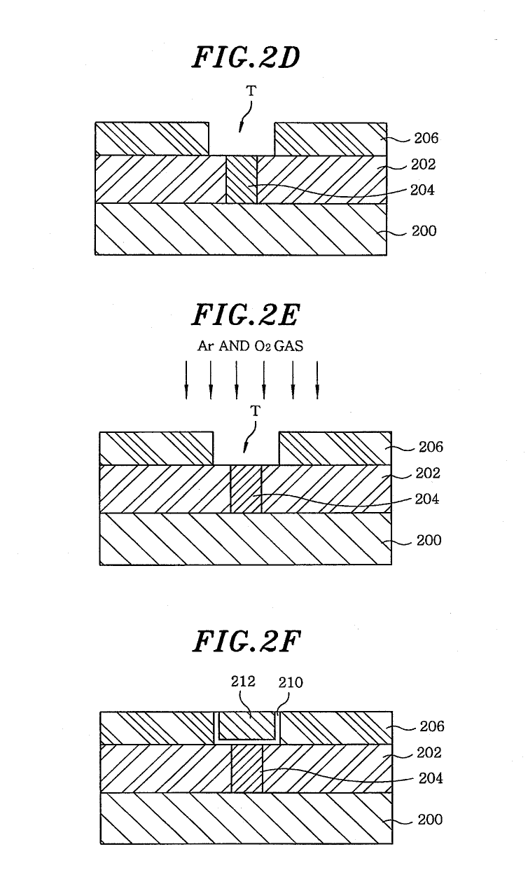

Example FIGS. 2A to 2F are cross-sectional views for a process of forming a metal line in a semiconductor device in accordance with embodiments.

### DESCRIPTION

Embodiments relate to a method for forming a metal line which can prevent a contact plug from being etched by residual gases. A cleaning process may be performed to remove gases, for example, fluorine and carbon, remaining after the formation of a contact plug and a trench in a single damascene process.

Example FIGS. 2A to 2F are cross-sectional views for a process of forming a metal line in a semiconductor device in accordance with embodiments. As illustrated in example FIG. 2A, a first interlayer insulating film 202 may be formed over a semiconductor substrate 200. A photoresist pattern for defining a contact hole may be formed over the first interlayer insulating film 202. A contact hole C may be formed by etching the first interlayer insulating film 202 using the photoresist pattern as an etching mask. The photoresist pattern may be removed by a stripping process. At this time, a fluorine gas may be used in an etching process for forming a contact hole. A large amount of carbon gas may be used for a sufficient etching selection ratio between the first interlayer insulating film 202 and the photoresist pattern.

Next, as shown in example FIG. 2B, a contact plug 204 may be formed by depositing a first metal material, for example, tungsten, in the contact hole C. Part of the fluorine gas and the carbon gas used to form the contact hole C is left after the formation of the contact plug 204.

Thereafter, as shown in example FIG. 2C, a second interlayer insulating film 206 may be formed over the semiconductor substrate 200 where the contact plug 204 is formed. A photoresist may be coated over the top of the second interlayer insulating film 206. A photoresist pattern 208 for a trench may be formed by a photolithographic process.

As shown in example FIG. 2D, a trench T may be formed by etching the second interlayer insulating film 206 using the photoresist pattern 208 as an etching mask. The photoresist pattern 208 for the trench may be removed by a stripping process.

Afterwards, as shown in example FIG. 2E, the residual gases, i.e., the carbon gas and fluorine gas, may be removed after the formation of the contact hole by carrying out a cleaning process on the semiconductor substrate 200 where the trench T is formed. The cleaning process may be carried out at a pressure of, for example, approximately 30 to 40 mTorr, using approximately 800 to 1400 W power source, preferably approximately 1100 W power source, and a bias power of approximately 180 to 220 W by use of O₂ gas at approximately 140 to 150 sccm and Ar gas at approximately 200 to 240 sccm for approximately 20 to 30 seconds, thereby removing the residual gases. That is, among the residual gases, the carbon gas may be removed by use of an O₂ gas, and the fluorine gas may be removed by use of an Ar gas.

Next, as shown in example FIG. 2F, a barrier metal film 210, for example, a copper barrier metal film, may be formed over the trench T. A metal line 212 connected to the contact plug 204 may be formed by depositing a second metal material, for example, copper. A chemical mechanical polishing process may be used to expose the top part of the second interlayer insulating film 206.

Although embodiments have been described by way of an example in which the residual gases are removed by use of oxygen and argon gases, only the argon gas may be used to remove only the fluorine, which has the largest effect on the size of the seam in the contact plug. According to embodiments, it is possible to avoid the etching of the contact plug by preventing tungsten of the contact plug and fluorine from being coupled to each other by removing the residual gases, carbon and fluorine, after the formation of a trench. Embodiments can improve the reliability of the semiconductor device by avoiding increase of the size of the seam formed in the contact plug. In addition, embodiments can prevent the contamination of copper to be formed in the trench by removing the residual gas, carbon.

It will be obvious and apparent to those skilled in the art that various modifications and variations can be made in the embodiments disclosed. Thus, it is intended that the disclosed embodiments cover the obvious and apparent modifications and variations, provided that they are within the scope of the appended claims and their equivalents.

What is claimed is:

1. A method comprising:
patterning a part of a first interlayer insulating film over a semiconductor substrate to form a contact hole therein;
depositing a first metal in the contact hole to form a metal contact plug;
forming a second interlayer insulating film over the semiconductor substrate where the metal contact plug is formed;
etching the second interlayer insulating film to form a trench;
removing residual gases from the formation of the metal contact plug after the formation of the trench; and
depositing a second metal in the trench to form a metal film connected to the metal contact plug.

2. The method of claim 1, wherein removing the residual gases comprises a cleaning process on the semiconductor substrate having the trench formed thereon.

3. The method of claim 1, wherein the residual gases are removed using an argon gas.

4. The method of claim 1, wherein the residual gases are removed using an oxygen gas and an argon gas.

5. The method of claim 1, wherein the first metal is tungsten.

6. The method of claim 1, wherein the second metal is copper.

7. The method of claim 2, wherein the cleaning process is carried out at a pressure of approximately 30 to 40 mTorr.

8. The method of claim 2, wherein the cleaning process is carried out using approximately 800 to 1400 W power source.

9. The method of claim 8, wherein the cleaning process is carried out a bias power of approximately 180 to 220 W.

10. The method of claim 3, wherein the Ar gas is supplied at approximately 200 to 240 sccm.

11. The method of claim 10, wherein the Ar gas is supplied for approximately 20 to 30 seconds.

12. The method of claim 4, wherein the O₂ gas is supplied at approximately 140 to 150 sccm.

13. The method of claim 12, wherein the O₂ gas is supplied for approximately 20 to 30 seconds.

14. The method of claim 2, wherein the cleaning process is carried out at approximately 30 to 40 mTorr, using approximately 800 to 1400 W power source, and a bias power of approximately 180 to 220 W using O₂ gas at approximately 140 to 150 sccm and Ar gas at approximately 200 to 240 sccm for approximately 20 to 30 seconds, thereby removing the residual gases.

15. The method of claim 1, wherein after depositing a second metal in the trench to form a metal film connected to the metal contact plug, the second metal film is planarized using a chemical mechanical polishing process.

16. The method of claim 15, wherein the first and second metals together form a metal line.

17. The method of claim 15, wherein the chemical mechanical polishing process exposes the top part of the second interlayer insulating film.

18. An apparatus comprising:
a first interlayer insulating film formed over a semiconductor substrate and having a patterned contact hole therein;
a metal contact plug of a first metal formed in the contact hole;
a second interlayer insulating film with a trench over the semiconductor substrate having the metal contact plug formed thereon; and
a metal film of a second metal formed in the etched trench and connecting to the metal contact plug.

19. The apparatus of claim 18, wherein the first metal is tungsten.

20. The apparatus of claim 18, wherein the second metal is copper.
